(19) United States
(12) Patent Application Publication
(10) Pub. No.: US 2008/0179647 A1
(43) Pub. Date: Jul. 31, 2008

(54) SEMICONDUCTOR DEVICE COMPRISING A BARRIER INSULATING LAYER AND RELATED METHOD

(75) Inventors: Hyeoung-won Seo, Yongin-si (KR); Dong-hyun Kim, Suwon-si (KR); Kang-yoon Lee, Seongnam-si (KR); Seong-goo Kim, Songpa-gu (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/964,146

(22) Filed: Dec. 26, 2007

(30) Foreign Application Priority Data
Jan. 26, 2007 (KR) 10-2007-0008611

(51) Int. Cl. H01L 27/108; H01L 21/8239

(52) U.S. Cl. 257/296; 438/239; 438/294; 257/E27.084; 257/E21.645

(57) ABSTRACT

A semiconductor device comprising a barrier insulating layer and a related method of fabrication is disclosed. The semiconductor device semiconductor substrate includes a plurality of active regions, wherein active regions are defined by a device isolation layer and are disposed along a first direction; a plurality of bit line electrodes connected to the active regions, wherein each of the bit line electrodes extends along a second direction; and a plurality of first barrier insulating layers. Each of the first barrier insulating layers extends along a third direction, at least one of the first barrier insulating layers is disposed on a corresponding first portion of the device isolation layer disposed between two of the active regions, the two of the active regions are adjacent along the first direction, and the first direction and the second direction differ from one another.

### CROSS-REFERENCE TO RELATED APPLICATION

This application claims priority to Korean Patent Application No. 10-2007-0008611, filed on Jan. 26, 2007, the subject matter of which is hereby incorporated by reference in its entirety.

### BACKGROUND OF THE INVENTION

1. Field of the Invention

Embodiments of the invention relate to a semiconductor device and a method for fabricating the semiconductor device. In particular, embodiments of the invention relate to a semiconductor device comprising barrier insulating layers and a method for fabricating the semiconductor device.

2. Description of the Related Art

The respective sizes of patterns in a semiconductor device may be reduced in order to increase the degree of integration of the semiconductor device. However, to some extent, practical limits in the formation of relatively fine patterns using photolithography are being reached. For example, a process margin for contact plugs used in memory devices is being reduced. That is, the size of a contact plug has been reduced and the separation interval between contact plugs has been reduced. Accordingly, a bridge problem may occur between storage node layers connected to the contact plugs, and reliability of the memory device may be greatly reduced.

In addition, forming compactly arranged contact plugs or storage node layers in a semiconductor device having interconnection lines (e.g., bit line electrodes or gate electrodes) disposed around the contact plugs or storage node layers is even more difficult. It is more difficult because a possibility of a bridge forming between the interconnection lines and the contact plugs or between the interconnection lines and the storage nodes increases in that case. Therefore, highly expensive apparatuses for fabricating semiconductor devices have been required to form contact plugs or storage node layers having relatively fine patterns.

### SUMMARY OF THE INVENTION

Embodiments of the invention provide a semiconductor device that has a relatively high degree of integration and that has relatively high reliability. Embodiments of the invention also provide a method for fabricating the semiconductor device.

In one embodiment, the invention provides a semiconductor device comprising a semiconductor substrate comprising a first plurality of first active regions, wherein the first active regions of the first plurality of first active regions are defined by a device isolation layer, and are disposed along a first direction; a plurality of bit line electrodes connected to the first plurality of first active regions, wherein each of the bit line electrodes extends along a second direction; and a plurality of first barrier insulating layers. Each of the first barrier insulating layers extends along a third direction, at least one of the first barrier insulating layers is disposed on a corresponding first portion of the device isolation layer disposed between two first active regions of the first plurality of first active regions, and the two first active regions are adjacent along the first direction.

In another embodiment, the invention provides a method for fabricating a semiconductor device comprising forming a device isolation layer in a semiconductor substrate to define a first plurality of first active regions, wherein the first active regions of the first plurality of first active regions are disposed along a first direction; forming a plurality of bit line electrodes on the semiconductor substrate, wherein the bit line electrodes extend in a second direction and are connected to the first plurality of first active regions; forming an interlayer insulating layer partially surrounding the bit line electrodes; and forming a plurality of first barrier insulating layers in the interlayer insulating layer. Each of the first barrier insulating layers extends in a third direction, at least one of the first barrier insulating layers is disposed on a corresponding first portion of the device isolation layer disposed between two first active regions of the plurality of first active regions, and the two first active regions are adjacent along the first direction.

### BRIEF DESCRIPTION OF THE DRAWINGS

Embodiments of the invention will be described herein with reference to the accompanying drawings, in which:

FIGS. (FIGS.) 1, 3, 5, 7, 9, and 11 are plan views illustrating a method for fabricating a semiconductor device in accordance with an embodiment of the invention;

FIGS. 2, 4, 6, 8, 10, and 12 are cross sectional views taken along a line I′-I′ of FIGS. 1, 3, 5, 7, 9, and 11, respectively, that also illustrate the method illustrated by FIGS. 2, 4, 6, 8, 10, and 12, in accordance with an embodiment of the invention;

FIGS. 11 and 12 also illustrate an intermediate structure in the fabrication of semiconductor memory device in accordance with an embodiment of the invention;

FIG. 13 is a cross sectional view illustrating an intermediate structure in the fabrication of a semiconductor device in accordance with another embodiment of the invention;

FIGS. 14 through 16 illustrate a method for fabricating a semiconductor device in accordance with still another embodiment of the invention, wherein FIG. 14 is a plan view of an intermediate structure in the fabrication of a semiconductor device, FIG. 15 is a cross-sectional view taken along a line I′-I′ of FIG. 14, and FIG. 16 is a cross-sectional view illustrating an intermediate structure in the fabrication of a semiconductor device fabricated using the method illustrated in FIGS. 14 through 16;

FIG. 17 is a plan view illustrating an intermediate structure in the fabrication of a semiconductor device in accordance with still another embodiment of the invention; and

FIG. 18 is a plan view illustrating an intermediate structure in the fabrication of a semiconductor device in accordance with still another embodiment of the invention.

### DESCRIPTION OF EMBODIMENTS

In the drawings, the thicknesses of layers and regions are not necessarily to scale. In addition, as used herein, when a first component is described as being “on” a second component, the first component may be directly on the second component, or intervening components may be present.

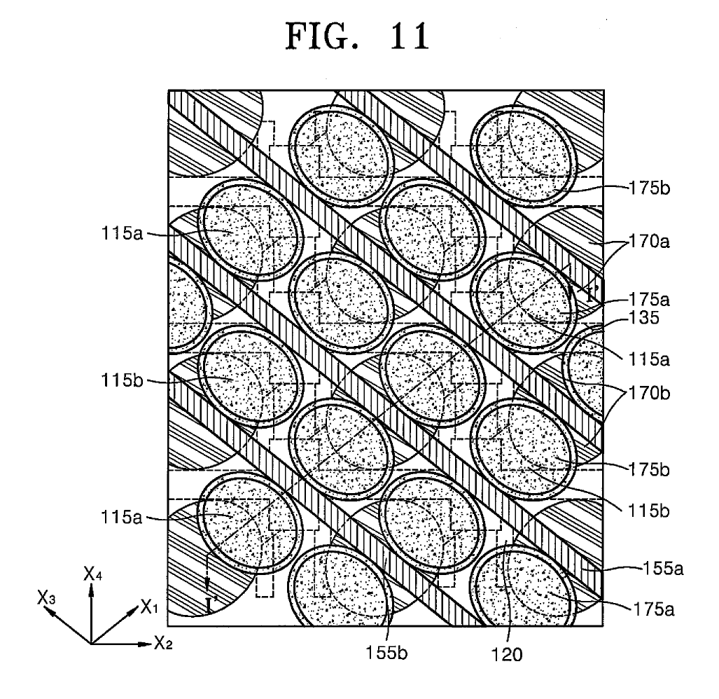

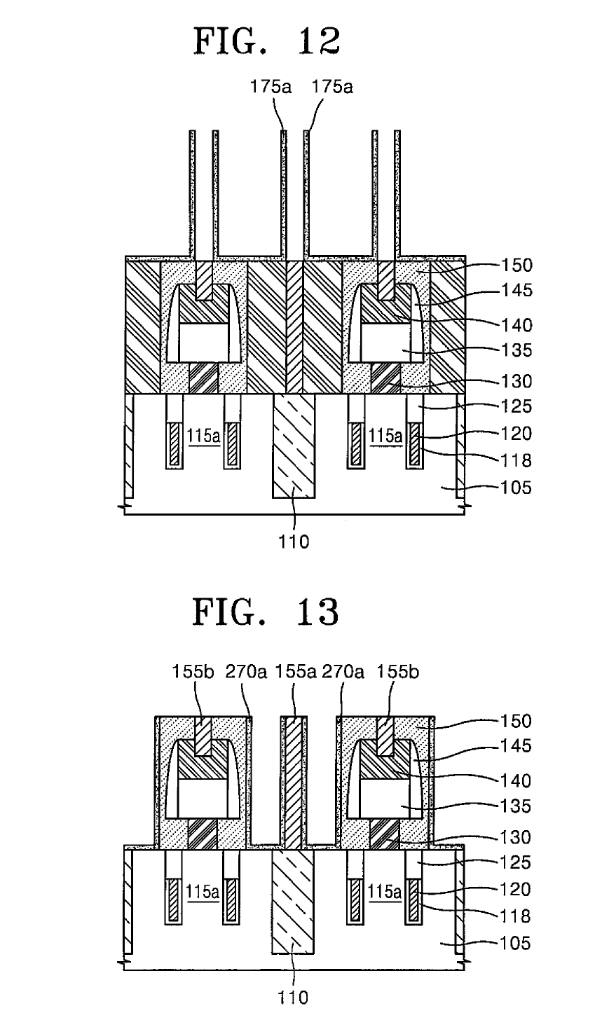

FIGS. 1 through 12 illustrate a method for fabricating a semiconductor device in accordance with an embodiment of the invention, and FIGS. 11 and 12 illustrate an intermediate structure in the fabrication of the semiconductor device in accordance with an embodiment of the invention.

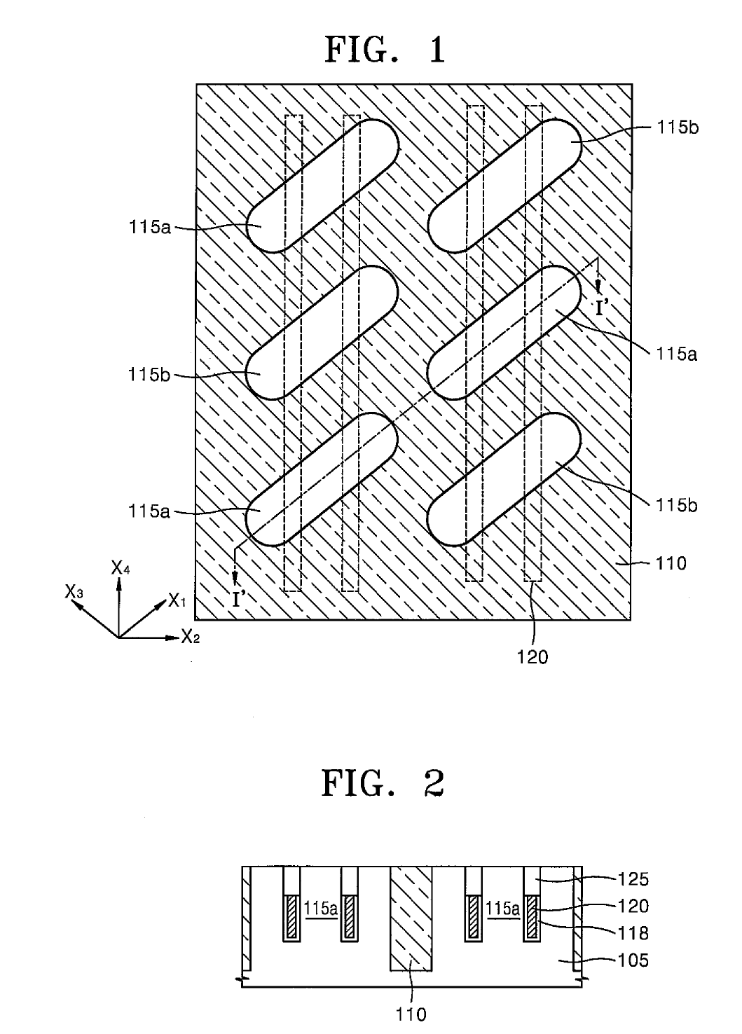

Referring to FIGS. 1 and 2, in the embodiment described with reference to FIGS. 1 through 12, a device isolation layer 110 is formed in a semiconductor substrate 105 to define a plurality of first active regions 115a and a plurality of second active regions 115b. Device isolation layer 110 may be formed by, for example, forming a trench in semiconductor substrate 105 and then filling the trench with an insulating layer. First and second active regions 115a and 115b may be defined by sidewalls of device isolation layer 110.

Directions X1 through X4 (i.e., first through fourth directions) will be used herein to describe embodiments of the invention. Directions X1 through X4 are illustrated in FIGS. 1, 3, 5, 7, 9, 11, 14, 17, and 18. As defined herein, each of directions X1 through X4 is parallel to the working surface of semiconductor substrate 105. Also, each “direction” is defined by an arrow indicated in the drawings and includes the direction indicated by the arrow (i.e., the positive direction) and the direction opposite the direction in which the arrow is pointing (i.e., the negative direction). In addition, all lines parallel to the arrow extend in the direction defined by the arrow. For example, direction X1 is defined by the arrow indicating direction X1 in the drawings, and a line extending from the arrow indicating direction X1 (both in the direction and opposite of the direction in which the arrow is pointing) and all lines parallel to the arrow indicating direction X1 also extend along direction X1. In addition, when two directions are said to “differ” it means that a single line cannot extend in both of those two directions, and that two lines respectively extending in those two directions are not parallel either.

First and second active regions 115a and 115b may be arranged along direction X1 (i.e., a first direction), for example. In the embodiment described with reference to FIGS. 1 through 12, first active regions 115a are disposed along direction X1, and second active regions 115b are also disposed along direction X1. That is, first active regions 115a are disposed along lines extending in direction X1, and second active regions 115b are also disposed along lines extending in direction X1. First active regions 115a disposed along the same line are separated from one another along direction X1. Likewise, second active regions 115b disposed along the same line are separated from one another along direction X1. However, in the embodiment described with reference to FIGS. 1 through 12, no first active region 115a is disposed along the same line extending in direction X1 as a second active region 115b. That is, no first active region 115a is separated from a second active region 115b along direction X1. In addition, as illustrated in FIG. 1, for example, lines in direction X1 along which first active region(s) 115a are disposed may be alternately arranged with lines in direction X1 along which second active regions 115(b) are disposed. Such an alternating arrangement is advantageous for achieving a relatively high degree of integration in the semiconductor device being fabricated.

Alternately, first and second active regions 115a and 115b may be described as being arranged in a matrix. In this case, the name may be reversed or not identified. For example, referring to FIG. 1, a first active region 115a and a second active region 115b may be described as being disposed along a single line extending in a direction X2 (i.e., a second direction). Thus, the arrangement of first and second active regions 115a and 115b may described in different ways, but such description does not restrict the scope of the invention as defined by the accompanying claims.

As used herein, when an element (which may be a hole) is said to “extend” in a particular direction, it means that the element's greatest dimension in a plane substantially parallel to the working surface of semiconductor substrate 105 is along a line extending in that direction. For example, referring to FIG. 1, the greatest dimension of first active region 115a is along a line that extends in direction X1, so first active region 115a may be said to extend in direction X1.

In the embodiment described with reference to FIGS. 1 through 12, each of first active regions 115a and second active regions 115b extends in direction X1. Therefore, for a group of first active regions 115a arranged along a line extending in direction X1, the first active regions 115a of that group are arranged along the same direction as the direction in which each of the first active regions 115a of that group extends. That is, those first active regions 115a are disposed along and each extend in direction X1. Likewise, for a group of second active regions 115b arranged along a line extending in direction X1, the second active regions 115b of that group are arranged along the same direction as the direction in which each of the second active regions 115b of that group extends. However, in modified versions of the embodiment described with reference to FIGS. 1 through 12, active regions may be arranged along a line that extends in a different direction than the direction in which each of the active regions extends.

Referring to FIGS. 1 and 2, a plurality of gate electrodes 120 are recessed into inner portions of first and second active regions 115a and 115b. Accordingly, gate electrodes 120 may be disposed below upper surfaces of first and second active regions 115a and 115b. In addition, gate insulating films 118 are interposed between gate electrodes 120 and first active regions 115a and between gate electrodes 120 and second active regions 115b. Capping insulating layers 125 are formed on gate electrodes 120. Gate electrodes 120 form word lines and extend in a direction X4 (i.e., a fourth direction). Gate electrodes 120 may not extend in the same direction as first and second active regions 115a and 115b. In the embodiment of FIGS. 1 through 12, gate electrodes 120 extend in direction X4 and first and second active regions 115a and 115b extend in direction X1. Device isolation layer 110 may comprise, for example, an oxide film, and capping insulating layer 125 may comprise, for example, a nitride film.

In addition, source/drain regions (not shown) may be defined in first and second active regions 115a and 115b on both sides of gate electrodes 120. That is, source/drain regions may be defined in a first active region 115a on a first side of a pair of gate electrodes 120 and on a second side of the pair of gate electrodes 120, and source/drain regions may be defined in a second active region 115b on a first side of a pair of gate electrodes 120 and on a second side of the pair of gate electrodes 120. The source/drain regions may be formed by implanting impurities into semiconductor substrate 105.

However, embodiments of the invention are not limited to the structure described above for gate electrodes 120. For example, in a modified version of the embodiment described with reference to FIGS. 1 through 12, planar type gate electrodes 120 are disposed on the upper surfaces of first and second active regions 115a and 115b.

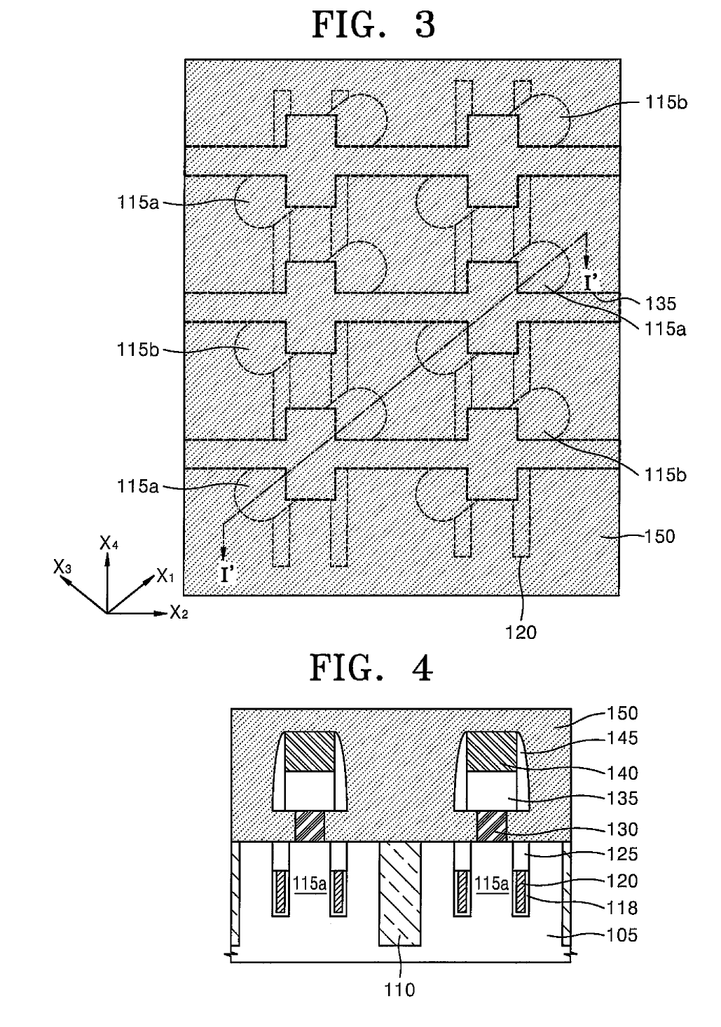

Referring to FIGS. 3 and 4, in the embodiment described with reference to FIGS. 1 through 12, a plurality of bit line electrodes 135 are connected to first active regions 115a and second active regions 115b. Bit line electrodes 135 may extend in a different direction than the direction in which gate electrodes 120 extend. For example, bit line electrodes 135 may extend in direction X2 (i.e., the second direction) and be connected alternately to first and second active regions 115a and 115b. Also, bit line electrodes 135 may optionally comprise tabs protruding in both the positive direction X4 and the negative direction X4 (i.e., protruding in directions opposite to one another but both along direction X4).

Bit line electrodes 135 may each extend in a different direction than the direction in which first and second active regions 115a and 115b extend. In the embodiment described with reference to FIGS. 1 through 12, each bit line electrode 135 extends in direction X2, and first and second active regions 115a and 115b each extend in direction X1. However, in another embodiment, which is a modification of the embodiment described with reference to FIGS. 1 through 12, direction X2 may correspond to direction X1. In that case, bit line electrodes 135 are commonly connected to only one of first and second active regions 115a and 115b.

Bit line electrodes 135 are connected to first active regions 115a and/or second active regions 115b using plugs 130. In the embodiment described with reference to FIGS. 1 through 12, bit line electrodes 135 are connected to first active regions 115a and second active regions 115b using plugs 130. In addition, capping insulating layers 140 are formed on bit line electrodes 135, and spacer insulating layers 145 are formed on sidewalls of bit line electrodes 135 and capping insulating layers 140.

More specifically, a portion of an interlayer insulating layer 150 comprising plugs 130 is formed. Then, bit line electrodes 135 and capping insulating layers 140 are formed, and spacer insulating layers 145 are formed on the sidewalls of bit line electrodes 135 and capping insulating layers 140. Subsequently, more of interlayer insulating layer 150 may be formed to cover bit line electrodes 135, capping insulating layers 140, and spacer insulating layers 145.

Spacer insulating layers 145 and capping insulating layers 140 may have an etch selectivity with respect to interlayer insulating layer 150. For example, interlayer insulating layer 150 may comprise an oxide film, and capping insulating layers 140 and spacer insulating layers 145 may each comprise a nitride film. Interlayer insulating layer 150 may be a single layer or have a multi-layer structure.

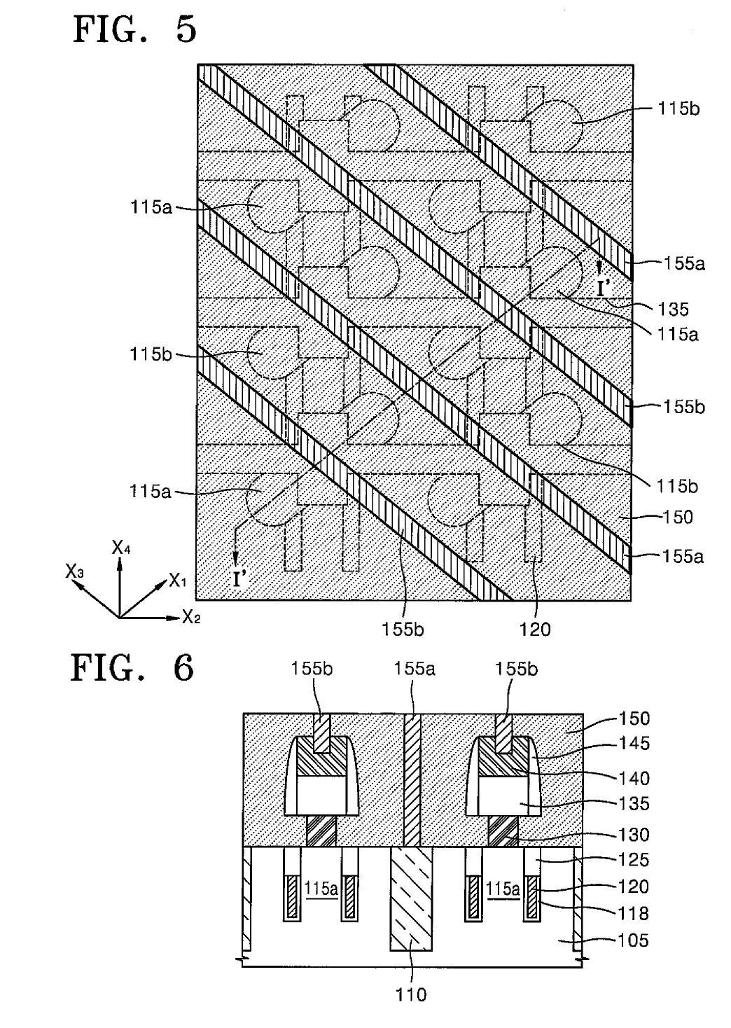

In a modified version of the embodiment described with reference to FIGS. 1 through 12, an etch stop layer (not shown) may be formed on semiconductor substrate 105 before forming interlayer insulating layer 150. In addition, before forming the etch stop layer, a buffer layer (not shown) may be formed. The etch stop layer prevents over etching of interlayer insulating layer 150 when first and second barrier insulating layers 155a and 155b of FIG. 6 are formed subsequently. The etch stop layer may comprise a nitride film, for example, and the buffer layer may comprise an oxide film, for example.

Referring to FIGS. 5 and 6, in the embodiment described with reference to FIGS. 1 through 12, a plurality of first barrier insulating layers 155a and a plurality of second barrier insulating layers 155b are formed. First barrier insulating layers 155a are disposed on portions of device isolation layer 110 disposed between adjacent first active regions 115a, and second barrier insulating layers 155b are disposed portions of device isolation layer 110 disposed between adjacent second active regions 115b. Each of first barrier insulating layers 155a and each of second barrier insulating layers 155b extends along a direction X3 (i.e., a third direction). Also, in the embodiment described with reference to FIGS. 1 through 12, for example, direction X3 differs from direction X2, and directions X1, X2, and X3 all differ from one another.

In the embodiment described with reference to FIGS. 1 through 12, for example, first portions of first barrier insulating layers 155a penetrate through interlayer insulating layer 150 between adjacent first active regions 115a to contact device isolation layer 110. First barrier insulating layers 155a may also be recessed into device isolation layer 110. In addition, first barrier insulating layers 155a extend over second active regions 115b, and second portions of first barrier insulating layers 155a are disposed on bit line electrodes 135 disposed on second active regions 115b. In more detail, the second portions of first barrier insulating layers 155a may contact capping insulating layers 140 or may be recessed into capping insulating layers 140.

Similarly, first portions of second barrier insulating layers 155b penetrate through interlayer insulating layer 150 between second active regions 115b and contact device isolation layer 110 or are recessed into device isolation layer 110. In addition, second barrier insulating layers 155b extend over first active regions 115a, and second portions of second barrier insulating layers 155b may be disposed on bit line electrodes 135 disposed on first active regions 115a. In more detail, the second portions of second barrier insulating layers 155b may contact capping insulating layers 140 or may be recessed into capping insulating layers 140. Referring to FIG. 6, in the embodiment described with reference to FIGS. 1 through 12, second barrier insulating layers 155b are recessed into capping insulating layers 140.

In accordance with embodiments of the invention, first and second barrier insulating layers 155a and 155b may be formed simultaneously, first barrier insulating layers 155a may be formed before second barrier insulating layers 155b, or second barrier insulating layers 155b may be formed before first barrier insulating layers 155a. Because first and second barrier insulating layers 155a and 155b can define an etch range of interlayer insulating layer 150, they may have an etch selectivity with respect to interlayer insulating layer 150. For example, first and second barrier insulating layers 155a and 155b may comprise a nitride film.

In a modified version of the embodiment described with reference to FIGS. 1 through 12, if first and second active regions 115a and 115b are not distinguished, first and second barrier insulating layers 155a and 155b may not be distinguished.

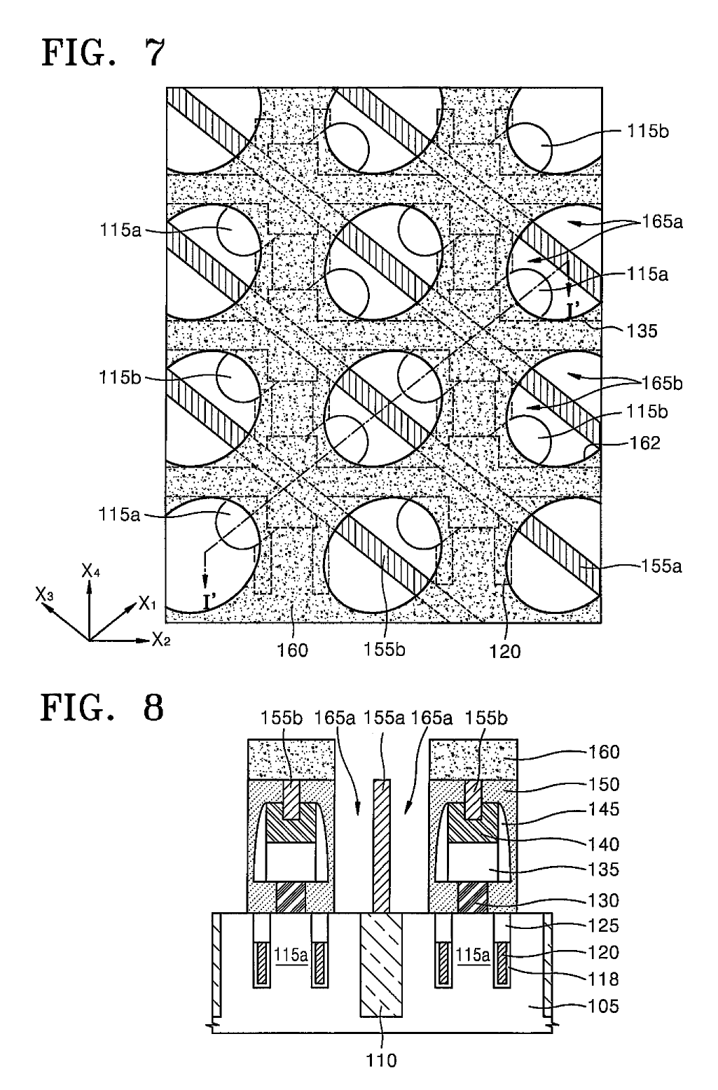

Referring to FIGS. 7 and 8, a plurality of first contact holes 165a exposing ends of first active regions 115a and a plurality of second contact holes 165b exposing ends of second active regions 115b are formed in interlayer insulating layer 150. The ends of first and second active regions 115a and 115b exposed by first and second contact holes 165a and 165b may be source/drain regions.

First and second contact holes 165a and 165b may be formed by, for example, etching interlayer insulating layer 150 using a mask pattern 160 as an etch protection film. Mask pattern 160 may, for example, comprise openings 162, each extending in direction X1, that expose portions of interlayer insulating layer 150 disposed on adjacent ends of adjacent first active regions 115a and portions of interlayer insulating layer 150 disposed on adjacent ends of adjacent second active regions 115b. First and second barrier insulating layers 155a and 155b may extend across holes formed in interlayer insulating layer 150, wherein the holes correspond to openings 162 of mask pattern 160. Mask pattern 160 may comprise a photoresist pattern, for example.

When etching interlayer insulating layer 150, first and second barrier insulating layers 155a and 155b may be etched a relatively small amount. Thus, each first contact hole 165a is partially defined by a first barrier insulating layer 155a, and each second contact hole 165b is partially defined by a second barrier insulating layer 155b. In particular, adjacent first contact holes 165a that do not have a portion of a bit line electrode 135 disposed between them are divided by a portion of one of first barrier insulating layers 155a, and adjacent second contact holes 165b that do not have a portion of a bit line electrode 135 disposed between them are divided by a portion of one of second insulating layers 155b.

As a result, first contact holes 165a can reliably be formed separate but closely adjacent to one another, and second contact holes 165b can also reliably be formed separate but closely adjacent to one another. Also, because of first and second barrier insulating layers 155a and 155b, a process margin with respect to mask pattern 160 for forming first and second contact holes 165a and 165b can be increased.

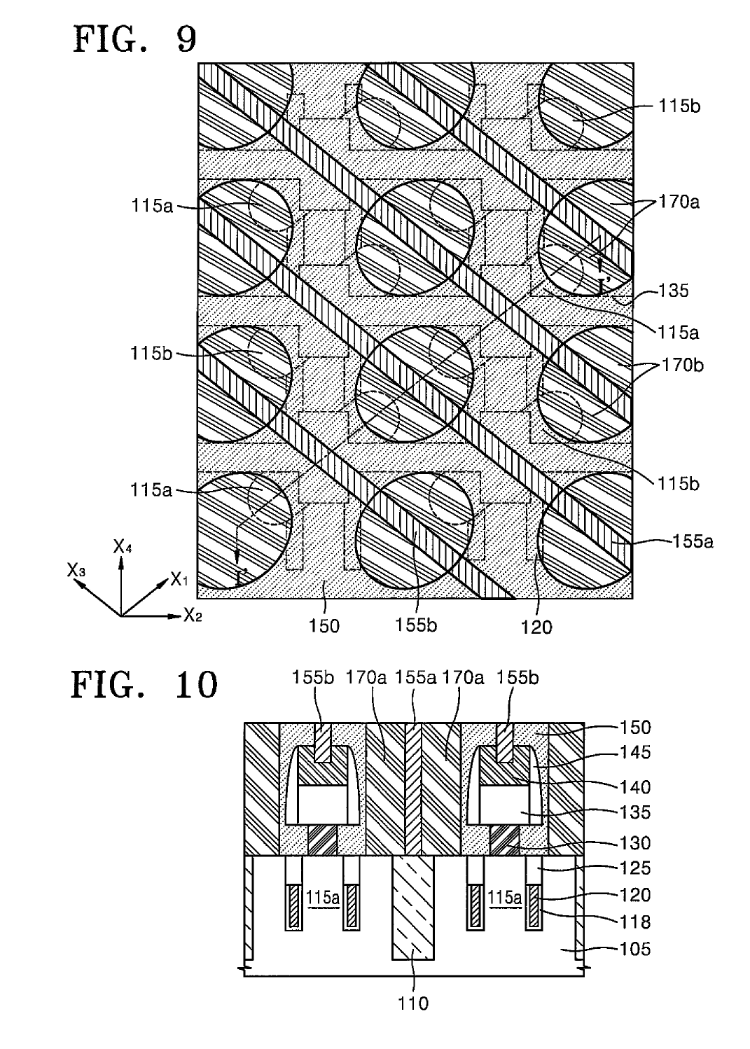

Referring to FIGS. 9 and 10, first and second contact holes 165a and 165b are filled with a conductive layer to form first and second contact plugs 170a and 170b. The conductive layer may be planarized so that the conductive layer remains only in first and second contact holes 165a and 165b. The planarization may be performed by chemical mechanical polishing (CMP) or an etch-back process, for example.

First contact plugs 170a are connected to portions (i.e., the source/drain regions) of first active regions 115a. In addition, second contact plugs 170b are connected to portions (i.e., the source/drain regions) of second active regions 115b. Sidewalls of first contact plugs 170a contact first barrier insulating layers 155a, and sidewalls of second contact plugs 170b contact second barrier insulating layers 155b.

Adjacent first contact plugs 170a are either separated from each other by a portion of one of first barrier insulating layers 155a, or have a portion of one of bit line electrodes 135 disposed between them. That is, a portion of one of first barrier insulating layers 155a separates a first pair of first contact plugs 170a that are adjacent along direction X1 (i.e., a portion of one of first barrier insulating layers 155a is disposed between first pair of first contact plugs 170a), and a portion of one of bit line electrodes 135 is disposed between a second pair of first contact plugs 170a that are adjacent along direction X1. In addition, the first and second pairs of adjacent contact plugs 170a may have a first contact plug 170a in common. That is, one first contact plug 170a may be in both the first and second pairs of adjacent contact plugs 170a. In addition, as used herein, when a first component is said to “separate” a pair of second components (or the pair of second components is said to be “separated by” the first components), it means that the two second components that make up the pair are separated by the first component. Likewise, as used herein, when a first component is said to be “disposed between” a pair of second components, it means that the first component is disposed between the two second components that make up the pair of second components. In addition, as used herein, “pairs” of components are not necessarily distinct from one another, so a single first component may be included in a first pair of the first components and in a second pair of the first components.

Similarly, adjacent second contact plugs 170b are either separated from each other by a portion of one of second barrier insulating layers 155b, or a portion of one of bit line electrodes 135 is disposed between them. That is, a portion of one of second barrier insulating layers 155b separates a first pair of adjacent second contact plugs 170b that are adjacent along direction X1, and a portion of one of bit line electrodes 135 is disposed between a second pair of adjacent second contact plugs 170b that are adjacent along direction X1. In addition, one second contact plug 170b may be in both the first and second pairs of adjacent contact plugs 170b.

Thus, each pair of adjacent first contact plugs 170a disposed on a portion of device isolation layer 110 can be separated by a portion of one of first barrier insulating layers 155a. Likewise, each pair of adjacent second contact plugs 170b disposed on a portion of device isolation layer 110 can be separated by a portion of one of second barrier insulating layers 155b. Accordingly, first contact plugs 170a can be reliably separated from one another even when they are arranged relatively closely together, and second contact plugs 170b can be reliably separated from one another even when they are arranged relatively closely together. Thus, the possibility of a bridge being formed between first contact plugs 170a or between second contact plugs 170b can be reduced. When first and second contact plugs 170a and 170b have a compact arrangement, the respective lengths of first and second active regions 115a and 115b can be reduced, which in turn contributes to improving the degree of integration of the semiconductor device in which those components are disposed.

Referring to FIGS. 11 and 12, first storage node layers 175a are formed on first contact plugs 170a, and second storage node layers 175b are formed on second contact plugs 170b. First and second storage node layers 175a and 175b may be, in a DRAM device, for example, lower electrodes of a capacitor. First and second storage node layers 175a and 175b may be readily separated by using first and second barrier insulating layers 155a and 155b as references. Therefore, a possibility of producing a bridge between first and second storage node layers 175a and 175b may be reduced.

The semiconductor device in accordance with the embodiment described with reference to FIGS. 1 through 12 is not limited to DRAM devices, so first and second storage node layers 175a and 175b can be omitted or modified to have other forms.

After the processes described with reference to FIGS. 1 through 12 are performed, a semiconductor device corresponding to the intermediate structure illustrated in FIGS. 1 through 12 is completed through a method well-known to one of ordinary skill in the art.

In the semiconductor device in accordance with the embodiment described with reference to FIGS. 1 through 12, first barrier insulating layers 155a are disposed on portions of device isolation layer 110 disposed between adjacent first active regions 115a, and second barrier insulating layers 155b are disposed on portions of device isolation layer 110 disposed between adjacent second active regions 115b. In addition, first barrier insulating layers 155a separate elements disposed on adjacent first active regions 115a, and second barrier insulating layers 155b separate elements disposed on adjacent second active regions 115b. Therefore, a separation interval between some adjacent first contact plugs 170a electrically connected to first active regions 115a can be decreased while substantially preventing a bridge from being produced between them, and a separation interval between some adjacent second contact plugs 170b electrically connected to second active regions 115b can be decreased while substantially preventing a bridge from being produced between them. Accordingly, the degree of integration of a semiconductor device in accordance with an embodiment of the invention may be increased, and the reliability of the semiconductor device may be improved as well.

FIG. 13 is a cross sectional view illustrating an intermediate structure in the fabrication of a semiconductor device in accordance with another embodiment of the invention. The embodiment described with reference to FIG. 13 is a modified version of the embodiment described with reference to FIGS. 1 through 12. Thus, description of features and/or processes common to both embodiments may be omitted here.

FIG. 13 corresponds to FIGS. 10 and 12. Accordingly, the process described with reference to FIGS. 1 through 8 is performed unchanged for the embodiment described with reference to FIG. 13.

Referring to FIG. 13, first storage node layers 270a are formed in first contact holes 165a of FIG. 8. Also, second storage node layers (not shown) may be formed in second contact holes 165b of FIG. 7. Therefore, first and second contact plugs 170a and 170b illustrated in FIGS. 9 through 12 may be omitted in the embodiment described with reference to FIG. 13.

First storage node layers 270a may be connected to first active regions 115a, and second storage node layers may be connected to second active regions 115b. Adjacent first storage node layers 270a either have a portion of one of bit line electrodes 135 disposed between them, or are separated by a portion of one of first barrier insulating layers 155a (i.e., have one of first barrier insulating layers 155a disposed between them). Consequently, the likelihood of a bridge forming between first storage node layers 270a may be substantially reduced. For example, a portion of one of bit line electrodes 135 may be disposed between a first pair of adjacent first storage node layers 270a, and a portion of one of first barrier insulating layers 155a may be disposed between a second pair of adjacent first storage node layers 270a. Also, adjacent second storage node layers either have a portion of one of bit line electrodes 135 disposed between them, or are separated by a portion of one of second barrier insulating layers 155b. Consequently, the likelihood of a bridge forming between second storage node layers may be substantially reduced.

For each first storage node layer 270a, one sidewall of first storage node layer 270a contacts one of first barrier insulating layers 155a. In addition, two first storage node layers 270a may be arranged adjacent to one another on opposite sides of one of first barrier insulating layers 155a. Similarly, for each second storage node layer, one sidewall of second storage node layer contacts one of second barrier insulating layers 155b. In addition, two second storage node layers may be arranged adjacent to one another on opposite sides of one of second barrier insulating layers 155b. Accordingly, the degree of integration of the semiconductor device may be improved.

In a modified version of the embodiment described with reference to FIG. 13, the respective heights of first and second barrier insulating layers 155a and 155b may be greater than in the embodiment described with reference to FIG. 13 so that the respective heights of first storage node layers 270a and the second storage node layers may be greater than in the embodiment described with reference to FIG. 13.

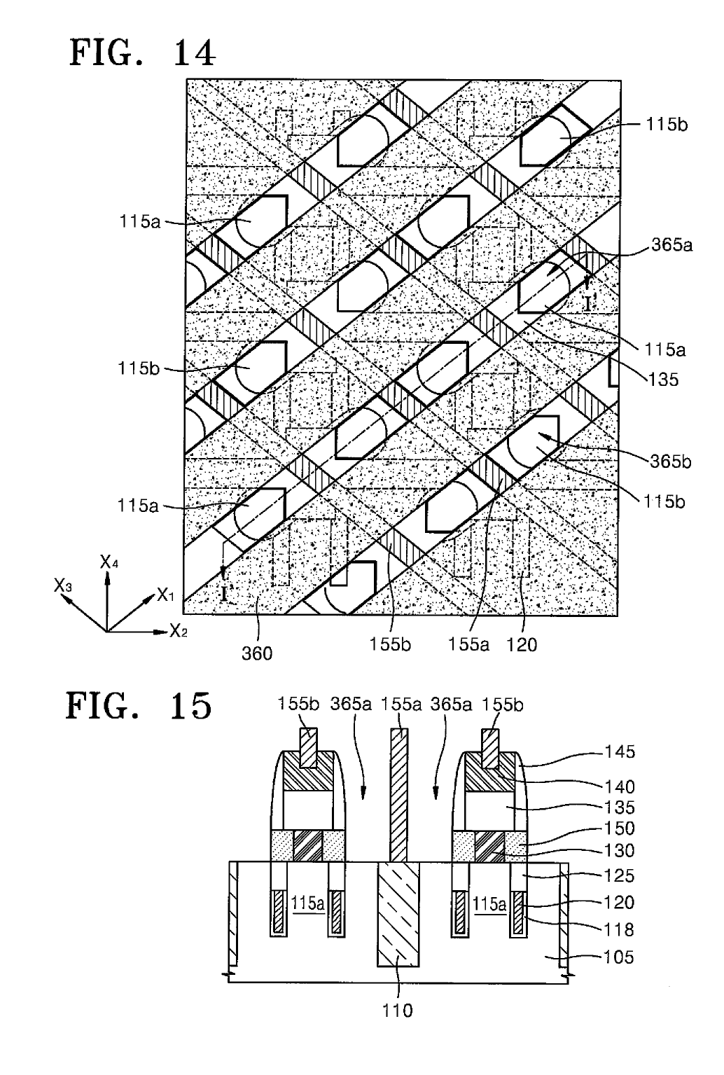

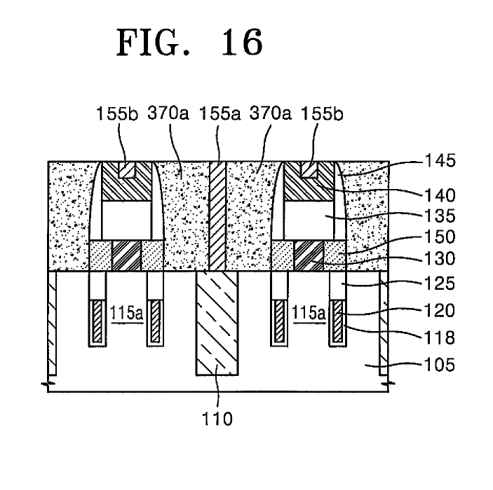

FIGS. 14 through 16 illustrate a method for fabricating a semiconductor device in accordance with an embodiment of the invention. FIG. 14 is a plan view of an intermediate structure in the fabrication of a semiconductor device in accordance with an embodiment of the invention, FIG. 15 is a cross sectional view taken along a line I′-I′ of FIG. 14, and FIG. 16 is a cross sectional view illustrating an intermediate structure in the fabrication of a semiconductor device in accordance with an embodiment of the invention. The embodiment described with reference to FIGS. 14 through 16 is a modified version of the embodiment described with reference to FIGS. 1 through 12. Therefore, description of features and/or processes common to both embodiments may be omitted here.

FIGS. 14 and 15 correspond to FIGS. 7 and 8, and FIG. 16 corresponds to FIG. 10. Thus, description relative to FIGS. 14 and 15 begins where description relative to FIGS. 1 through 6 ends.

Referring to FIGS. 14 and 15, a plurality of first contact holes 365a exposing ends of first active regions 115a and a plurality of second contact holes 365b exposing ends of second active regions 115b are formed in an interlayer insulating layer 150. Using a mask pattern 360 as an etch protection film, first and second contact holes 365a and 365b are formed by etching interlayer insulating layer 150.

Mask pattern 360 may, for example, have a line-type pattern, wherein portions of mask pattern 360 are disposed between first active regions 115a and second active regions 115b and extend in direction X1. First contact holes 365a are defined in part by first barrier insulating layers 155a and spacer insulating layers 145 disposed on sidewalls of bit line electrodes 135. Similarly, second contact holes 365b are defined in part by second barrier insulating layers 155b and spacer insulating layers 145 disposed on sidewalls of bit line electrodes 135.

That is, first contact holes 365a are self-aligned, and adjacent first contact holes 365a either have a portion of one of bit line electrodes 135 disposed between them, or are separated by a portion of one of first barrier insulating layers 155a. Similarly, second contact holes 365b are self-aligned, and adjacent second contact holes 365b either have a portion of one of bit line electrodes 135 disposed between them, or are separated by a portion of one of second barrier insulating layers 155b. Because such a line-type mask pattern 360 can be readily formed, a process margin for forming first and second contact holes 365a and 365b can be greatly improved. Mask pattern 360 may comprise a photoresist pattern, for example.

Referring to FIGS. 14 through 16, first contact holes 365a and second contact holes 365b are filled with a conductive layer to form first contact plugs 370a and second contact plugs (not shown). The conductive layer may, for example, be planarized so that it is defined within (i.e., remains only in) first and second contact holes 365a and 365b. Planarization may be performed using CMP or an etch-back process. When performing planarization, upper surfaces of first and second barrier layers 155a and 155b may be partially removed to an extent that the upper surfaces of first and second barrier layers 155a and 155b are level with upper surfaces of capping insulating layers 140.

In the embodiment described with reference to FIGS. 14 through 16, first contact plugs 370a are self-aligned between spacer insulating layers 145 disposed on sidewalls of bit line electrodes 135 and first barrier insulating layers 155a. Similarly, the second contact plugs are self-aligned between spacer insulating layers 145 disposed on sidewalls of bit line electrodes 135 and second barrier insulating layers 155b.

Therefore, for each first contact plug 370a, one sidewall contacts one of first barrier insulating layers 155a, and another sidewall contacts one of spacer insulating layers 145. Similarly, for each second contact plug, one sidewall contacts one of second barrier insulating layers 155b, and another sidewall contacts one of spacer insulating layers 145. When they are separated by a portion of one of first barrier insulating layers 155a, adjacent first contact plugs 370a can be reliably separated despite being disposed relatively close to one another. Similarly, when they are separated by a portion of one of second barrier insulating layers 155b, adjacent second contact plugs can be reliably separated despite being disposed relatively close to one another. As a result, the likelihood of a bridge being formed between adjacent first contact plugs 370a disposed relatively close to one another or between adjacent second contact plugs disposed relatively close to one another may be reduced.

Subsequently, similar to the embodiment described with reference to FIGS. 11 and 12, first storage node layers 175a are formed on first contact plugs 370a, and second storage node layers 175b are formed on second contact plugs.

In a modified version of the embodiment described with reference to FIGS. 14 through 16, the process illustrated in FIG. 16 is omitted. Then, similar to the embodiment described with reference to FIG. 13, first storage node layers 270a are formed within first contact holes 365a of FIG. 15, and second storage node layers are formed within second contact holes 365b. That is, first storage node layers 270a and second storage node layers may be self-aligned.

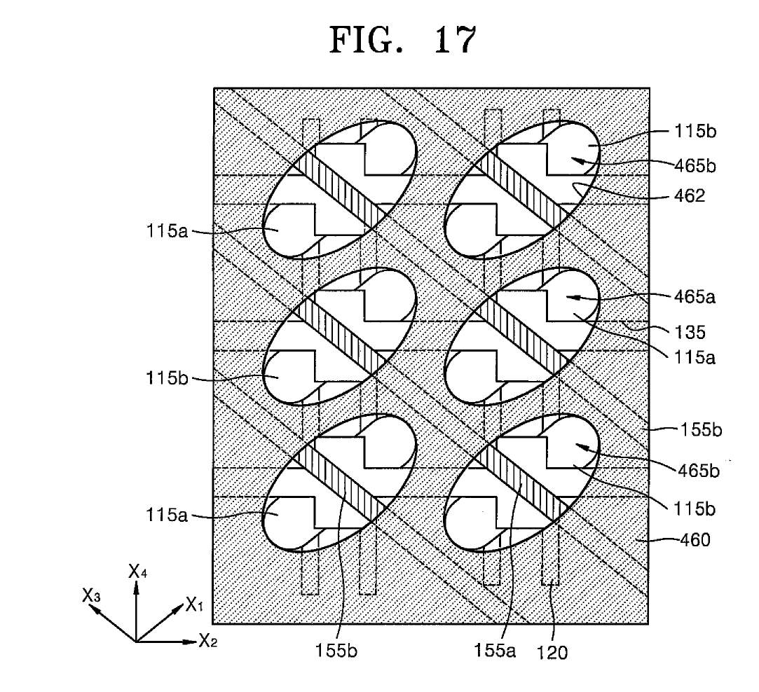

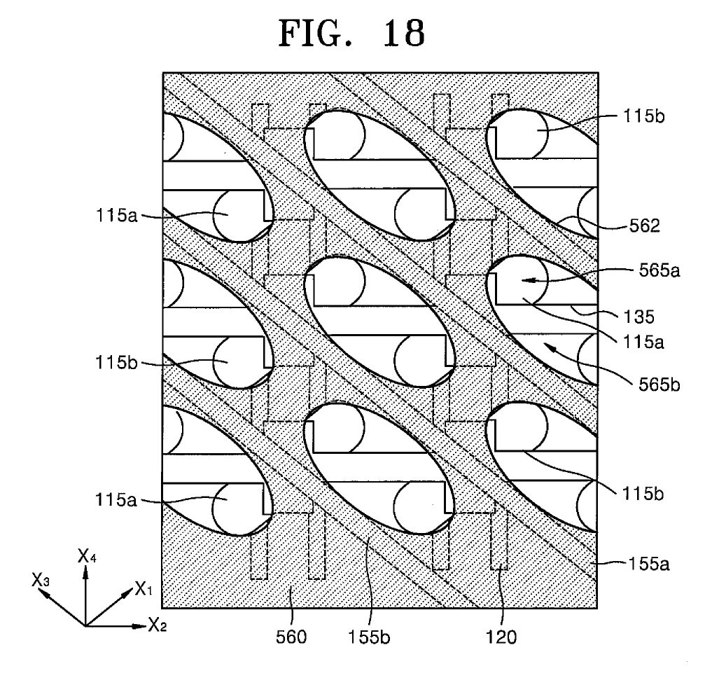

FIG. 17 is a plan view illustrating an intermediate structure in the fabrication of a semiconductor device in accordance with another embodiment of the invention. The embodiment described with reference to FIG. 17 is a modified version of the embodiment described with reference to FIGS. 1 through 12. Thus, description of features and/or processes common to both embodiments may be omitted here.

FIG. 17 corresponds to FIG. 7. Therefore, processes described with reference to FIG. 17 may be preformed after the processes described with reference to FIGS. 1 through 6 are performed.

Referring to FIG. 17, a plurality of first contact holes 465a exposing ends of first active regions 115a and a plurality of second contact holes 465b exposing ends of second active regions 115b are formed in interlayer insulating layer 150. First and second contact holes 465a and 465b are formed by etching interlayer insulating layer 150 using a mask pattern 460 as an etch protection film.

In the embodiment described with reference to FIG. 17, for example, mask pattern 460 comprises openings 462, which each extend in direction X1 and each expose a portion of interlayer insulating layer 150 disposed over either one of first active regions 115a or one of second active regions 115b. By etching the portions of interlayer insulating layer 150 exposed by openings 462, first contact holes 465a separated by spacer insulating layers 145 disposed on bit line electrodes 135 are formed, and second contact holes 465b separated by spacer insulating layers 145 disposed on bit line electrodes 135 are formed. In this way, first contact holes 465a can be disposed adjacent to one another in direction X1 and reliably separated can be formed, and second contact holes 465b can be disposed adjacent to one another in direction X1 and reliably separated can be formed.

Additionally, if openings 462 are misaligned, first barrier insulating layers 155a can further separate first contact holes 465a, and second barrier insulating layers 155b can further separate second contact holes 465b. Accordingly, a process margin for forming first and second contact holes 465a and 465b can be greatly improved.

Subsequent processes in the fabrication of a semiconductor device corresponding to the intermediate structure illustrated in FIG. 17 may be similar to the processes described with reference to FIGS. 9 through 12 or the processes described with reference to FIG. 13.

FIG. 18 is a plan view illustrating an intermediate structure in the fabrication of semiconductor device in accordance with another embodiment of the invention. The embodiment described with reference to FIG. 18 is a modified version of the embodiment described with reference to FIGS. 1 through 12. Thus, description of features and/or processes common to both embodiments may be omitted here.

For example, FIG. 18 corresponds to FIG. 7. Therefore, processes described with reference to FIG. 18 may be performed after processes described with reference to FIGS. 1 through 6 are performed.

Referring to FIG. 18, a plurality of first contact holes 565a exposing ends of first active regions 115a and a plurality of second contact holes 565b exposing ends of second active regions 115b are formed in interlayer insulating layer 150. First and second contact holes 565a and 565b are formed by etching interlayer insulating layer 150, using a mask pattern 560 as an etch protection film.

For example, mask pattern 560 comprises openings 562, each of which extends in direction X3 and exposes a portion of interlayer insulating layer 150 disposed over one end of one of first active regions 115a and one end of one of second active regions 115b. By etching the portions of interlayer insulating layer 150 exposed by openings 562, first contact holes 565a and second contact holes 565b separated by portions of bit line electrodes 135, on which spacer insulating layers 145 are disposed, can be formed. Accordingly, first contact holes 565a and second contact holes 565b can be reliably separated while also being relatively closely adjacent to one another.

Moreover, if openings 562 are misaligned, first and second barrier insulating layers 155a and 155b may aid in separating adjacent first contact holes 565a and may aid in separating adjacent second contact holes 565b. Therefore, a process margin for forming first and second contact holes 565a and 565b can be greatly improved.

Subsequent processes in the fabrication of a semiconductor device corresponding to the intermediate structure illustrated in FIG. 18 may be similar to the processes described with reference to FIGS. 9 through 12 or the processes described with reference to FIG. 13.

In a semiconductor device in accordance with an embodiment of the invention, contact plugs may be reliably separated while also being disposed relatively near to one another. Therefore, in accordance with an embodiment of the invention, the likelihood that a bridge may be produced between contact plugs in a semiconductor device having a relatively high degree of integration may be reduced. Also, because the contact plugs are reliably separated from one another, the likelihood that a bridge will be produced between storage node layers formed over the contact plugs may be decreased. Furthermore, in accordance with embodiments of the invention, contact plugs or charge storage node layers may be self-aligned using spacer insulating layers disposed on bit line electrodes and barrier insulating layers. Also, in accordance with embodiments of the invention, a process margin for forming contact holes (and thus also for forming contact plugs and storage node layers) can be greatly improved.

Although embodiments of the invention have been described herein, various changes may be made to the embodiments by one of ordinary skill in the art without departing from the scope of the invention as defined by the accompanying claims.

What is claimed is:

1. A semiconductor device comprising:
a semiconductor substrate comprising a first plurality of first active regions, wherein the first active regions of the first plurality of first active regions are defined by a device isolation layer, and are disposed along a first direction;
a plurality of bit line electrodes connected to the first plurality of first active regions, wherein each of the bit line electrodes extends along a second direction; and
a plurality of first barrier insulating layers,
wherein each of the first barrier insulating layers extends along a third direction,
wherein at least one of the first barrier insulating layers is disposed on a corresponding first portion of the device isolation layer disposed between two first active regions of the first plurality of first active regions, and
wherein the two first active regions are adjacent along the first direction.

2. The semiconductor device of claim 1, wherein the first direction, the second direction, and the third direction differ from one another.

3. The semiconductor device of claim 1, further comprising a plurality of first storage node layers connected to the first plurality of first active regions, wherein one of the first barrier insulating layers is disposed between a first pair of the first storage node layers and one of the bit line electrodes is disposed between a second pair of the first storage node layers.

4. The semiconductor device of claim 1, further comprising a plurality of first contact plugs connected to the first plurality of first active regions, wherein a portion of one of the first barrier insulating layers is disposed between a first pair of the first contact plugs, and a portion of one of the bit line electrodes is disposed between a second pair of the first contact plugs.

5. The semiconductor device of claim 4, wherein one sidewall of each of the first contact plugs contacts a corresponding one of the first barrier insulating layers.

6. The semiconductor device of claim 4, further comprising a plurality of spacer insulating layers disposed on sidewalls of the bit line electrodes,
wherein each of the first contact plugs has a sidewall contacting a corresponding one of the first barrier insulating layers and is disposed between the corresponding one of the first barrier insulating layers and one of the spacer insulating layers.

7. The semiconductor device of claim 4, further comprising a plurality of first storage node layers connected to the first plurality of first contact plugs.

8. The semiconductor device of claim 4, further comprising an interlayer insulating layer disposed on the semiconductor substrate and at least partially surrounding each of the first contact plugs, each of the bit line electrodes, and each of the first barrier insulating layers,
wherein each of the first barrier insulating layers has an etch selectivity with respect to the interlayer insulating layer,
wherein the interlayer insulating layer comprises an oxide film, and
wherein each of the first barrier insulating layers comprises a nitride film.

9. The semiconductor device of claim 4, further comprising:
a plurality of second active regions, wherein the second active regions are disposed along the first direction;
a plurality of second barrier insulating layers extending along the third direction, wherein each of the second barrier insulating layers is disposed on a corresponding second portion of the device isolation layer disposed between two of the second active regions, wherein the two second active regions are adjacent along the first direction; and
a second plurality of first active regions,
wherein the first active regions of the second plurality of first active regions are disposed along the first direction, and
wherein the plurality of second active regions is disposed between the first plurality of first active regions and the second plurality of first active regions.

10. The semiconductor device of claim 9, wherein the bit line electrodes are also connected to the second active regions.

11. The semiconductor device of claim 9, wherein each of the first barrier insulating layers is disposed on a corresponding one of the second active regions; and
wherein each of the second barrier insulating layers is disposed on a corresponding first active region of the first plurality or the second plurality of first active regions.

12. The semiconductor device of claim 9, further comprising a plurality of second contact plugs connected to the second active regions, wherein a portion of one of the second barrier insulating layers is disposed between a first pair of the second contact plugs, and a portion of another one of the bit line electrodes is disposed between a second pair of the second contact plugs.

13. The semiconductor device of claim 12, further comprising a plurality of second storage node layers connected to the second contact plugs.

14. The semiconductor device of claim 9, further comprising a plurality of second storage node layers connected to the second active regions, wherein a portion of one of the second barrier insulating layers is disposed between a first pair of the second storage node layers, and a portion of another one of the bit line electrodes is disposed between a second pair of the second storage node layers.

15. A method for fabricating a semiconductor device comprising:
forming a device isolation layer in a semiconductor substrate to define a first plurality of first active regions, wherein the first active regions of the first plurality of first active regions are disposed along a first direction;
forming a plurality of bit line electrodes on the semiconductor substrate, wherein the bit line electrodes extend in a second direction and are connected to the first plurality of first active regions;
forming an interlayer insulating layer partially surrounding the bit line electrodes; and
forming a plurality of first barrier insulating layers in the interlayer insulating layer,
wherein each of the first barrier insulating layers extends in a third direction,
wherein at least one of the first barrier insulating layers is disposed on a corresponding first portion of the device isolation layer disposed between two first active regions of the plurality of first active regions, and
wherein the two first active regions are adjacent along the first direction.

16. The method of claim 15, further comprising forming a plurality of first contact plugs in the interlayer insulating layer and connected to the plurality of first active regions, wherein one of the first barrier insulating layers is disposed between a first pair of the first contact plugs and one of the bit line electrodes is disposed between a second pair of the first contact plugs.

17. The method of claim 16, wherein forming the plurality of first contact plugs comprises:
forming, in the interlayer insulating layer, a plurality of first contact holes exposing two ends of each of the first active regions of the plurality of first active regions, wherein each of the first contact holes exposes one of the ends of a corresponding one of the first active regions of the first plurality of first active regions; and
forming a conductive layer to fill the first contact holes.

18. The method of claim 17, wherein:
forming the plurality of first contact holes comprises using a mask pattern as an etch protection film;
the mask pattern comprises openings extending in the first direction;
each of at least some of the openings exposes a portion of the interlayer insulating film disposed on an end of each of only two adjacent first active regions of the first plurality of first active regions; and
the two adjacent first active regions are adjacent along the first direction.

19. The method of claim 17, wherein:
forming the plurality of first contact holes comprises using a mask pattern as an etch protection film; and
the mask pattern comprises openings, wherein each opening exposes a portion of the interlayer insulating film disposed on two ends of each of at least one of the first active regions of the first plurality of first active regions.

20. The method of claim 16, further comprising forming a plurality of first storage node layers on the interlayer insulating layer and connected to the plurality of first contact plugs.

21. The method of claim 15, further comprising forming a plurality of first storage node layers in the interlayer insulating layer,
wherein the plurality of first storage node layers is connected to the plurality of first active regions, and
wherein one of the first barrier insulating layers is disposed between a first pair of the plurality of first storage node layers and one of the bit line electrodes is disposed between a second pair of the plurality of first storage node layers.

22. The method of claim 15, wherein:
forming the device isolation layer further defines a plurality of second active regions, wherein the second active regions are disposed along the first direction;
forming the device isolation layer further defines a second plurality of first active regions, wherein the first active regions of the second plurality of first active regions are disposed along the first direction; and
the plurality of second active regions is disposed between the first and second pluralities of first active regions.

23. The method of claim 22, further comprising forming a plurality of second barrier insulating layers on the semiconductor substrate,
wherein each of the second barrier insulating layers extends in the third direction,
wherein each of the second barrier insulating layers is disposed on a corresponding second portion of the device isolation layer disposed between two of the second active regions, and
wherein the two second active regions are adjacent along the first direction.

24. The method of claim 23, further comprising:
forming a plurality of first contact plugs and a plurality of second contact plugs in the interlayer insulating layer,
wherein forming the plurality of first contact plugs and forming the plurality of second contact plugs comprises:
forming a plurality of contact holes exposing ends of the first active regions of the first and second pluralities of first active regions and exposing ends of the second active regions; and
forming a conductive layer to fill the contact holes,
wherein the plurality of first contact plugs are connected to the first active regions of the first and second pluralities of first active regions,
wherein a portion of one of the first barrier insulating layers is disposed between a first pair of the first contact plugs and a portion of one of the bit line electrodes is disposed between a second pair of the first contact plugs,
wherein the plurality of second contact plugs are connected to the plurality of second active regions, and
wherein a portion of one of the second barrier insulating layers is disposed between a first pair of the second contact plugs and a portion of another one of the bit line electrodes is disposed between a second pair of the second contact plugs.

25. The method of claim 24, wherein forming the plurality of contact holes comprises etching the interlayer insulating layer using a mask pattern having openings extending in the third direction as an etch protection film,
wherein each opening exposes a portion of the interlayer insulating layer disposed on an end of one of the first active regions and dispose on an end of one of the second active regions, and
wherein the bit line electrodes are also connected to the second active regions.
